(19) United States
(12) Patent Application Publication
(10) Pub. No.: US 2013/0105799 A1
(43) Pub. Date: May 2, 2013

(54) THIN FILM TRANSISTOR AND FLEXIBLE DISPLAY USING THE SAME

(71) Applicants: Sung Hwan Choi, Seoul (KR); Min Koo Han, Seoul (KR)

(72) Inventors: Sung Hwan Choi, Seoul (KR); Min Koo Han, Seoul (KR)

(73) Assignee: SNU R&DB FOUNDATION, Seoul (KR)

(21) Appl. No.: 13/326,474

(22) Filed: Dec. 15, 2011

(30) Foreign Application Priority Data
Oct. 31, 2011 (KR) 10-2011-0112166

(51) Int. Cl. H01L 29/786

(52) U.S. Cl. 257/59; 257/E29.273

(57) ABSTRACT

Provided are a thin film transistor having a passivation layer capable of annealing at low temperature and having stable electric characteristics, and a flexible display using the same. In one embodiment, the thin film transistor includes a passivation layer formed on an active layer, the passivation layer including a fluoropolymer.

### CROSS-REFERENCE TO RELATED APPLICATION

This application claims priority to and the benefit of Korean Patent Application No. 10-2011-0112166 filed on Oct. 31, 2011, which is herein incorporated by reference in its entirety.

### BACKGROUND OF THE INVENTION

1. Field of the Invention

The present invention relates to a thin film transistor having a passivation layer capable of annealing at low temperature and having stable electric characteristics, and a flexible display using the same.

2. Description of the Related Art

Recently, in order to achieve lightweight, large-area and flexible displays, a thin film transistor (TFT) using an indium-gallium-zinc-oxide (IGZO) semiconductor are drawing much attention. The flexible display is a flexible device using a roll-to-roll process for forming a flexible substrate with reduced manufacturing costs. In addition, since an oxide thin film transistor having an IGZO thin film has high mobility and uniformity and can be manufactured at a low temperature, compared to an amorphous silicon thin film transistor, it can be used for a flexible display.

However, since a threshold voltage of an IGZO thin film transistor is seriously changed according to various environmental factors, it is necessary to improve reliability of the IGZO thin film transistor for a flexible display.

In order to overcome the environmental factors, a variety of inorganic or organic passivation layers have been researched. PECVD-based silicon dioxide (SiO₂) or silicon nitride (SiNₓ) inorganic passivation layers may undergo deterioration in electrical characteristics of an IGZO thin film transistor due to plasma-induced radiation damages caused to a back-channel region of the IGZO thin film transistor.

In addition, the reliability of thin film transistor passivated with a polymeric material such as PVP or PMMA without plasma-induced radiation damages is poorer than that of the thin film transistor passivated with an inorganic insulating layer.

Further, hydrogen and moisture, which may be reduced with the use of a hydrophobic insulator, may cause instability of the IGZO thin film transistor under gate bias stress. Since an oxide thin film transistor for a flexible display is exposed to extrinsic environmental conditions, a passivation layer suitable for attaining long-term stability is required. In addition, during post heat treatment and passivation, a high processing temperature exceeding 200° C. may become serious impediment to the use of flexible substrates formed of polyethylene naphthalate (PEN) or polyethersulfone (PES), requiring a low processing temperature of 200° C. or less.

### SUMMARY OF THE INVENTION

Aspects of the present invention provide a thin film transistor having a passivation layer capable of annealing at low temperature and having stable electric characteristics, and a flexible display using the same.

In accordance with one aspect of the present invention, there is provided a thin film transistor for use in a flexible display, including a passivation layer formed on an active layer, the passivation layer including a fluoropolymer.

Here, the passivation layer may be formed of a CYTOP fluoropolymer.

In addition, the passivation layer may be formed by spin-coating the fluoropolymer in a solution state.

The passivation layer may be formed by annealing at 180° C. after the spin-coating.

In accordance with another aspect of the present invention, there is provided a flexible display using a thin film transistor, including a flexible substrate, and a passivation layer formed on the flexible substrate and having a thin film transistor formed on an active layer using a fluoropolymer.

Here, flexible substrate may be made of a material including polyethylene naphthalate (PEN) and polyethersulfone (PES).

The passivation layer may be formed of a CYTOP fluoropolymer.

In addition, the passivation layer may be formed by spin-coating the fluoropolymer in a solution state.

The passivation layer may be formed by annealing at 180° C. after the spin-coating.

As described above, since the thin film transistor according to the present invention includes a passivation layer formed of a fluoropolymer, a subthreshold swing of the thin film transistor can be reduced while increasing saturation mobility, and improving electrical characteristics by suppressing a threshold shift.

In addition, since the thin film transistor according to the present invention uses a passivation layer, it can be annealed at a lower temperature than in the conventional thin film transistor and formed on a flexible substrate to be applied to a flexible display.

Additional aspects and/or advantages of the invention will be set forth in part in the description which follows and, in part, will be obvious from the description, or may be learned by practice of the invention.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 is graph illustrating gate voltage (V_{GS})-drain current (I_{DS}) characteristics of thin film transistors according to Example of the present invention and Comparative Examples;

FIG. 2 is graph illustrating threshold voltage shifts (ΔVₜₕ) relative to stress time of thin film transistors according to Example of the present invention and Comparative Examples stressed in positive bias states;

FIG. 3 is graph illustrating threshold voltage shifts (ΔVₜₕ) relative to stress time of thin film transistors according to Example of the present invention and Comparative Examples stressed in negative bias states; and

FIG. 4 is a test result graph illustrating secondary ion mass spectrometry (SIMS) analyses of thin film transistors according to Example of the present invention and Comparative Examples.

In the following description, the same or similar elements are labeled with the same or similar reference numbers.

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Preferred embodiments will now be described more fully hereinafter with reference to the accompanying drawings. However, they may be embodied in different forms and should not be construed as limited to the embodiments set forth herein. Rather, these embodiments are provided so that this disclosure will be thorough and complete, and will fully convey the scope of the disclosure to those skilled in the art.

Hereinafter a configuration of a thin film transistor according to an embodiment of the present invention will be described.

The thin film transistor according to an embodiment of the present invention includes a passivation layer, like the conventional thin film transistor.

In the thin film transistor according to an embodiment of the present invention, the passivation layer is formed of an amorphous fluoropolymer. However, the present invention is not limited to such material.

Since the fluoropolymer is a good water repellent, electrical insulator and has considerably high transparency, it can be suitably used for a flexible display.

The passivation layer may include the fluoropolymer, specifically in a trade name ‘CYTOP’ commercially available from ASAHI GLASS. The passivation layer is deposited on an active layer of an oxide thin film transistor at room temperature in vacuum by spin-coating. It should be noted that the method for forming the passivation layer on the active layer of the oxide thin film transistor is not limited to the spin-coating. In addition, the passivation layer may be formed by spin-coating the fluoropolymer in a solution state.

After the process, annealing is performed at approximately 180° C. That is to say, the processing temperature of the thin film transistor according to the present invention can be lowered, compared to a case of the conventional process. Therefore, the thin film transistor according to the present invention can be suitably used with a flexible substrate formed of polyethylene naphthalate (PEN) or polyethersulfone (PES). Therefore, the thin film transistor according to the present invention can be used for a flexible display.

Hereinafter, various characteristics of the thin film transistor according to examples of the present invention and comparative examples will be described.

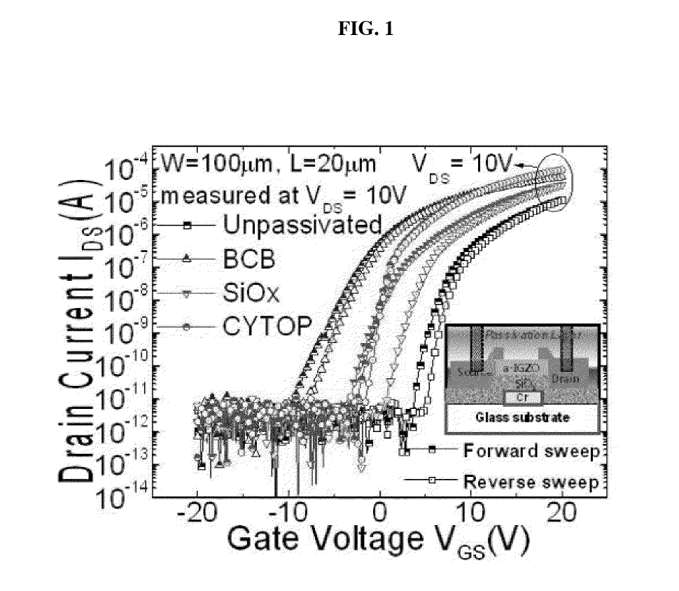

FIG. 1 is graph illustrating gate voltage (V_{GS})-drain current (I_{DS}) characteristics of thin film transistors according to Example of the present invention and Comparative Examples.

As described above, in the thin film transistor according to Example of the present invention, the passivation layer was formed using CYTOP manufactured by ASAHI GLASS as the fluoropolymer. A thin film transistor with a passivation layer formed of benzocyclobutene (BCB), a thin film transistor with a passivation layer formed of an inorganic material, such as silicon oxide (SiOx), and a thin film transistor without a passivation layer were compared with the thin film transistors according to Example of the present invention. The tests were carried out by evaluating electrical characteristics in a dark room using a semiconductor parameter analyzer B1500A manufactured by Agilent Technologies.

The thin film transistor according to Example of the present invention exhibited saturation mobility (μsat) of 12.3 [cm²/Vs] and subthreshold swing (ss) of 0.13[V/dec]. Here, the saturation mobility was calculated by the square root of a ratio of gate voltage (V_{GS}) versus drain current (I_{DS}).

By contrast, the thin film transistor using benzocyclobutene (BCB) as a passivation layer exhibited saturation mobility (μsat) of 4.8 [cm²/Vs] and subthreshold swing (ss) of 0.29[V/Dec]. The thin film transistor using inorganic SiO₂ exhibited saturation mobility (μsat) of 5.9 [cm²/Vs] and subthreshold swing (ss) of 0.40[V/Dec]. The unpassivated thin film transistor exhibited saturation mobility (μsat) of 6.4 [cm²/Vs]. The test results are shown in Table 1.

TABLE 1

| | Example | BCB | SiO₂ | Unpassivated |
|---|---|---|---|---|
| Saturation | 12.3 | 4.8 | 5.8 | 6.4 |
| mobility | | | | |
| [cm²/Vs] | | | | |
| Subthreshold | 0.35 | 0.65 | 0.57 | 0.40 |
| swing | | | | |
| [V/Dec] | | | | |
| ΔV_{TH} (V) | 0.2 | 0.4 | 2.5 | 0.8 |
| (forward/Reverse | | | | |
| sweep) | | | | |

As confirmed from Table 1, the thin film transistor according to Example of the present invention had much higher saturation mobility than the thin film transistors according to Comparative Examples. This is presumably caused by preventing plasma-induced radiation damages from being applied to a back-channel region of the thin film transistor using CYTOP as a passivation layer in adjusting deposition conditions of the passivation layer while stably forming an interference region between CYTOP and IGZO.

In addition, after CYTOP passivation, the thin film transistor according to Example of the present invention had a turn-on voltage shifted to the negative side (Vₜᵤᵣₙ₋ₒₙ=4.0[V]), whereas the thin film transistor using benzocyclobutene (BCB) had a turn-on voltage shifted more to the negative side (ΔVₜᵤᵣₙ₋ₒₙ=−10.6[V]). This is caused by a difference in the dielectric constant between benzocyclobutene (BCB) and CYTOP.

Hysteresis occurring to the thin film transistor according to Example of the present invention was considerably reduced (ΔVₜᵤᵣₙ₋ₒₙ=0.2[V]), compared to the unpassivated thin film transistor (ΔVₜᵤᵣₙ₋ₒₙ=1.4[V]). In addition, hysteresis occurring to the thin film transistor using silicon dioxide (SiO₂) was much seriously deteriorated (ΔVₜᵤᵣₙ₋ₒₙ=2.5[V]), compared to the thin film transistor according to Example of the present invention. This is due to the plasma induced radiation damages applied to a back channel region by ICP-CVD, suggesting that electrical characteristics of a bottom-gate IZGO thin film transistor significantly deteriorated.

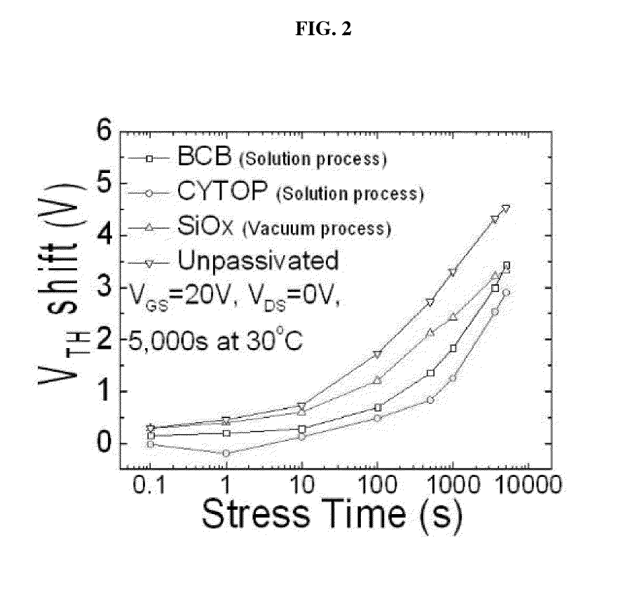

FIG. 2 is graph illustrating threshold voltage shifts (ΔVₜₕ) relative to stress time of thin film transistors according to Example of the present invention and Comparative Examples stressed in positive bias states.

The tests were carried out by applying a gate bias (V_{GS}) of 20[V] and a drain bias (V_{DS}) of 0[V] to oxide thin film transistors at 30° C. for 5,000 seconds.

Referring to FIG. 2, the thin film transistor according to Example of the present invention exhibited a threshold voltage shift (ΔVₜₕ) of 2.8 [V] over stress time. By contrast, under the same bias conditions, the thin film transistors using benzocyclobutene (BCB) and an inorganic material, e.g., silicon oxide (SiOx), as passivation layers exhibited threshold voltage shifts (ΔVₜₕ) of 3.4[V] and 3.3[V], respectively. That is to say, in states where the saturation mobility and subthreshold swing (ss) remained unchanged, the threshold voltage shift (ΔVₜₕ) of the thin film transistor according to Example of the present invention was smaller than that of the unpassivated thin film transistor, which was shifted by 4.5[V], with respect to bias-temperature-stress. The test results are shown in Table 2.

TABLE 2

| | Example | BCB | SiO₂ | Unpassivated |
|---|---|---|---|---|
| Threshold | 2.8 | 3.4 | 3.3 | 4.5 |
| voltage shift | | | | |
| [V] | | | | |

As confirmed from Table 2, the thin film transistor according to Example of the present invention using fluoropolymer (CYTOP) as a passivation layer had a reduced threshold voltage shift, compared to the thin film transistors according to Comparative Examples. Therefore, according to the present invention, an electrically reliable thin film transistor can be achieved.

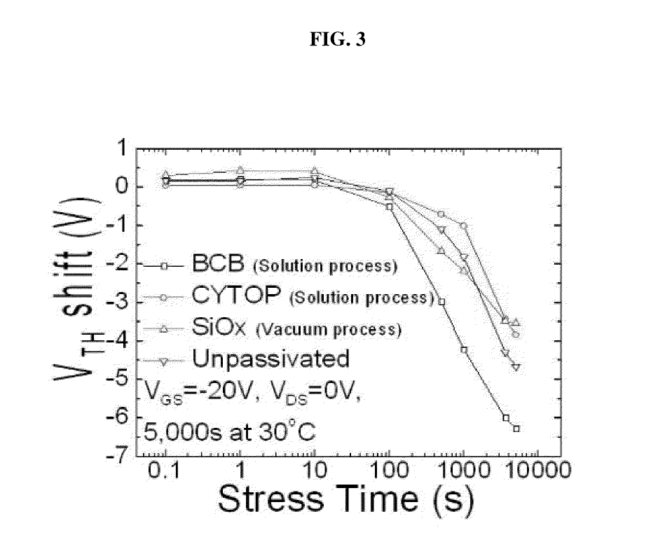

FIG. 3 is graph illustrating threshold voltage (V_{TH}) shifts relative to stress time of thin film transistors according to Example of the present invention and Comparative Examples stressed in negative bias states.

The tests were carried out by applying a gate bias (V_{GS}) of −20[V] and a drain bias (V_{DS}) of 0[V] to oxide thin film transistors at 30° C. for 5,000 seconds.

Referring to FIG. 3, the CYTOP-passivated thin film transistor according to Example of the present invention exhibited a threshold voltage shift (ΔVₜₕ) of −3.8[V] over stress time. By contrast, the thin film transistors using benzocyclobutene (BCB) and an inorganic material, e.g., silicon oxide (SiOx), as passivation layers exhibited threshold voltage shifts (ΔVₜₕ) of −6.2[V] and −3.5[V], respectively.

The test results showed that the CYTOP-passivated thin film transistor according to Example of the present invention had bias-temperature stability, compared to the SiOx-passivated thin film transistor. The unpassivated thin film transistor exhibited a threshold voltage shift of −4.6[V]. The test results are shown in Table 3.

TABLE 3

| | Example | BCB | SiO₂ | Unpassivated |
|---|---|---|---|---|
| Threshold | −3.8 | −6.2 | −3.5 | −4.6 |
| voltage shift | | | | |
| [V] | | | | |

Under bias-temperature stress conditions, instability of a threshold voltage (Vₜₕ) of an IGZO thin film transistor is associated with extrinsic conditions, e.g., a chemical reaction between a back-channel region and extrinsic oxygen/vapor. Chemical adsorption of oxygen and desorption of vapor around a back-interface of a channel region, which are caused by the bias-temperature stress conditions, may result in instability of threshold voltage. A solution of a passivation layer may play an important role for a highly functional IGZO thin film transistor.

Under the bias-temperature stress conditions, threshold voltage differences among the thin film transistors may be caused by different passivation layers which can prevent extrinsic environments from affecting threshold voltage shifts. In particular, the thin film transistor with a passivation layer using an inorganic material (SiO₂) had small plasma induced radiation damage with respect to an IGZO active layer in the IGZO back-channel region and exhibited relatively low interaction between the IGZO back-channel and the CYTOP passivation layer.

The thin film transistor according to Example of the present invention did not show a considerable deviation in the threshold voltage shift, suggesting that the electrical reliability of the thin film transistor according to Example of the present invention was higher than the thin film transistor using an inorganic passivation layer made of (SiOx). In addition, the thin film transistor using benzocyclobutene (BCB) and the unpassivated thin film transistor had were an inorganic material, e.g., silicon oxide (SiOx), as passivation layers exhibited threshold voltage shifts of −6.2[V] and −4.6[V], respectively. Therefore, the thin film transistor according to Example of the present invention exhibited improved reliability.

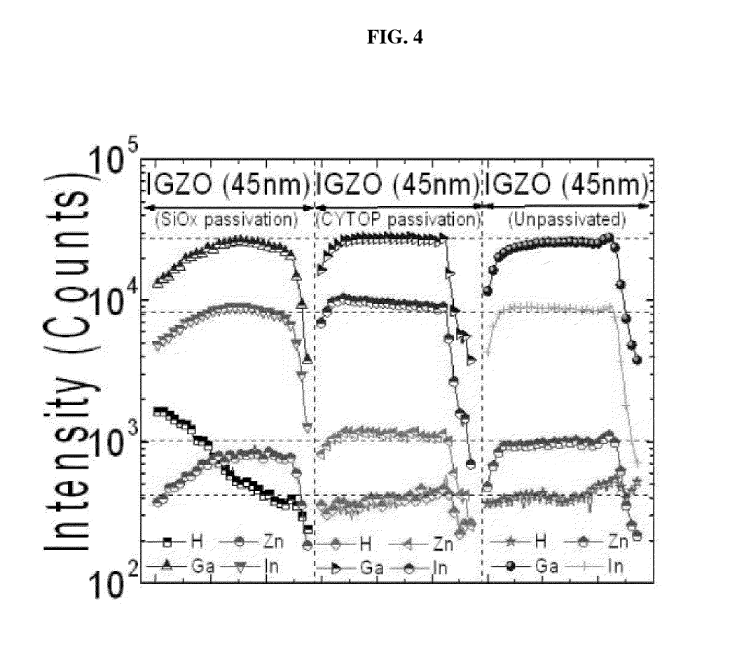

FIG. 4 is a test result graph illustrating secondary ion mass spectrometry (SIMS) analyses of thin film transistors according to Example of the present invention and Comparative Examples.

In order to determine whether impurities exist in an IGZO thin film, the tests were carried out to investigate depth profiles of atoms of three oxide thin film transistors using time-of-flight secondary ion mass spectroscopy (TOF-SIMS). In SISM, cesium ion (Cs+) beams were used as a primary ion source with an energy of 10 [KeV] and current of approximately 50.0 [nA]. The depth profiles of zinc (Zn), gallium (Ga) and hydrogen (H) atoms of thin film transistors using BCB, inorganic material (SiOx) and CYTOP passivation layers are shown in FIG. 4.

Referring to FIG. 4, the thin film transistor using an inorganic (SiOx) passivation layer exhibited relatively reduced intensities of zinc (Zn), gallium (Ga) and hydrogen (H) ions, compared to the thin film transistor according to Example of the present invention using a CYTOP passivation layer. In addition, thin film transistor using an inorganic (SiOx) passivation layer exhibited remarkably increased hydrogen (H) ion intensity in the IZGO thin film, compared to the thin film transistor having CYTOP passivation layer.

This suggests that the thin film transistor using an inorganic (SiOx) passivation layer underwent serious decomposition of the IZGO thin film, compared to the thin film transistor according to Example of the present invention using a CYTOP passivation layer. In addition, it is considered that during CVD-based passivation, hydrogen ions (H+) were diffused into the IZGO thin film by high density plasma.

Therefore, since the thin film transistor according to Example of the present invention using a CYTOP passivation layer has improved electrical characteristic and bias stability, compared to the thin film transistor using an inorganic (SiOx) passivation layer, it is possible to prevent mutual diffusion of indium (In), gallium (Ga) and zinc (Zn) atoms into regions between the passivation layer and the IGZO layer (i.e., channel layer).

As described above, the thin film transistor according to Example of the present invention shows less degradation and improved positive bias-temperature reliability by forming a passivation layer formed of an appropriate fluoropolymer (e.g., CYTOP), compared to existing oxide thin film transistors. In addition, the thin film transistor according to Example of the present invention has high saturation mobility in an oxide thin film transistor using a good combination of an IGZO active layer and a fluoropolymer (CYTOP) passivation layer. The improved extrinsic environment-opposed passivation layer is suitable to increase electrical bias-temperature stability of a bottom-gate amorphous IGZO thin film transistor.

Although the thin film transistor according to an exemplary embodiment of the present invention has been described in detail hereinabove, it should be understood that many variations and modifications of the basic inventive concept herein described, which may appear to those skilled in the art, will still fall within the spirit and scope of the exemplary embodiments of the present invention as defined by the appended claims.

The drawings and the forgoing description gave examples of the present invention. The scope of the present invention, however, is by no means limited by these specific examples. Numerous variations, whether explicitly given in the specification or not, such as differences in structure, dimension, and use of material, are possible. The scope of the invention is at least as broad as given by the following claims.

What is claimed is:

1. A thin film transistor for use in a flexible display, comprising a passivation layer formed on an active layer, the passivation layer including a fluoropolymer.

2. The thin film transistor of claim 1, wherein the passivation layer is formed of a CYTOP fluoropolymer.

3. The thin film transistor of claim 1, wherein the passivation layer is formed by spin-coating the fluoropolymer in a solution state.

4. The thin film transistor of claim 3, wherein the passivation layer is formed by annealing at approximately 180° C. after the spin-coating.

5. The thin film transistor of claim 3, wherein the spin-coating is done at room temperature in vacuum condition.

6. A flexible display using a thin film transistor, comprising:
a flexible substrate; and
a thin film transistor formed on the flexible substrate, the thin film transistor having a passivation layer formed on an active layer using fluoropolymer.

7. The flexible display of claim 6, wherein the flexible substrate is made of a material including polyethylene naphthalate (PEN) and polyethersulfone (PES).

8. The flexible display of claim 6, wherein the passivation layer is formed of a CYTOP fluoropolymer.

9. The flexible display of claim 6, wherein the passivation layer is formed by spin-coating the fluoropolymer in a solution state.

10. The flexible display of claim 9, wherein the passivation layer is formed by annealing at approximately 180° C. after the spin-coating.

11. The thin film transistor of claim 9, wherein the spin-coating is done at room temperature in vacuum condition.

12. A flexible display using a thin film transistor comprising:
a flexible substrate; and
a thin film transistor formed on the flexible substrate, the thin film transistor comprising an active layer and a passivation layer made of fluoropolymer material and formed on the active layer, wherein the thin film transistor having a saturation mobility within the range of 10 cm²/Vs to 15 cm²/Vs.

13. The flexible display of claim 12, wherein the flexible substrate is made of a material including polyethylene naphthalate (PEN) and polyethersulfone (PES).

14. The flexible display of claim 12, wherein the passivation layer is formed of a CYTOP fluoropolymer.

15. The flexible display of claim 12, wherein the passivation layer is formed by spin-coating the fluoropolymer in a solution state.

16. The flexible display of claim 15, wherein the passivation layer is formed by annealing at approximately 180° C. after the spin-coating.

17. The thin film transistor of claim 15, wherein the spin-coating is done at room temperature in vacuum condition.

18. The thin film transistor of claim 12, wherein the saturation mobility of the thin film transistor is 12.3 cm²/Vs.

19. The flexible display of claim 12, wherein the flexible substrate is made of polyethylene naphthalate (PEN).

20. The flexible display of claim 12, wherein the flexible substrate is made of polyethersulfone (PES).
